(19) United States
(12) Patent Application Publication
(10) Pub. No.: US 2026/0107812 A1
(43) Pub. Date: Apr. 16, 2026

(54) METHOD FOR FORMING AN ELECTRONIC DEVICE WITH A GLASS SUBSTRATE

(71) Applicant: JCET STATS ChipPAC Korea Limited, Incheon (KR)

(72) Inventors: MinSung LEE, Incheon (KR); YeoJun YUN, Incheon (KR); HeeSoo LEE, Incheon (KR)

(21) Appl. No.: 19/357,095

(22) Filed: Oct. 14, 2025

(30) Foreign Application Priority Data
Oct. 14, 2024 (CN) 202411432056.4

(51) Int. Cl. H01L 23/00; H01L 21/48

(52) U.S. Cl. CPC H10W 72/072; H10W 70/093; H10W 70/095; H10W 72/0198; H10W 72/07235; H10W 72/07236; H10W 72/241

(57) ABSTRACT

A method for forming an electronic device is provided, comprising: providing a glass substrate, wherein the glass substrate has on its top surface a top redistribution layer; attaching an electronic component on the top redistribution layer of the glass substrate; bonding the electronic component onto the top redistribution layer by applying laser assisted bonding through the glass substrate; forming an encapsulant layer on the glass substrate to encapsulate the electronic component and the top redistribution layer; forming through vias in the glass substrate; forming a bottom redistribution layer onto a bottom surface of the glass substrate; and mounting solder bumps onto the bottom redistribution layer.

### TECHNICAL FIELD

The present application generally relates to electronic technology, and more particularly, to a method for forming an electronic device with a glass substrate.

### BACKGROUND OF THE INVENTION

The electronic industry is constantly faced with complex integration challenges as consumers want their electronics to be smaller, faster and higher performance with more and more functionalities packed into a single device. In order to meet the needs of the consumers, more and more electronic components are integrated in a single device. Specifically, electronic components such as semiconductor chips need to be bonded on a substrate such as a polymer-based printed circuit board to form an integrated device or package.

Furthermore, glass wafers are being considered as a promising replacement of the polymer-based substrates for electronic components, which exhibit many advantages such as superior thermal stability, optical transparency, chemical resistance, etc. However, conventional bonding processes are low in in efficiency for bonding electronic components onto glass substrates.

Therefore, a need exists for a method for bonding one or more electronic components onto a glass substrate to form an electronic device.

### SUMMARY OF THE INVENTION

An objective of the present application is to provide a method for bonding one or more electronic components onto a glass substrate to form an electronic device.

According to an aspect of the present application, a method for forming an electronic device is provided, comprising: providing a glass substrate, wherein the glass substrate has on its top surface a top redistribution layer; attaching an electronic component on the top redistribution layer of the glass substrate; bonding the electronic component onto the top redistribution layer by applying laser assisted bonding through the glass substrate; forming an encapsulant layer on the glass substrate to encapsulate the electronic component and the top redistribution layer; forming through vias in the glass substrate; forming a bottom redistribution layer onto a bottom surface of the glass substrate; and mounting solder bumps onto the bottom redistribution layer.

According to another aspect of the present application, a method for forming an electronic device is provided, comprising: providing a glass substrate, wherein the glass substrate comprises a top surface and a bottom surface; forming through vias in the glass substrate; forming a top redistribution layer on the top surface of the glass substrate; attaching an electronic component on the top redistribution layer; bonding the electronic component onto the top redistribution layer by applying laser assisted bonding through the glass substrate; forming an encapsulant layer on the glass substrate to encapsulate the electronic component and the top redistribution layer; forming a bottom redistribution layer on the bottom surface of the glass substrate; and mounting solder bumps onto the bottom redistribution layer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1K show cross-sectional views illustrating a method for forming an electronic device according to an embodiment of the present application.

FIGS. 2A to 2K show cross-sectional views illustrating a method for forming an electronic device according to another embodiment of the present application.

FIGS. 3A to 3C show various alternative ways for applying laser assisted bonding according to some embodiments of the present application.

FIG. 4 illustrates a temperature profile of a solder material on a glass substrate during a laser assisted bonding process according to an example of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In an electronic device such as an integrated semiconductor package, one or more electronic components need to be bonded to a substrate. Many technologies have been developed for the bonding process, which are mostly applied to silicon substrates or polymer substrates, or particularly to solder materials formed between the substrates and the electronic components thereon. Yet, the conventional bonding technologies may not be suitable for bonding electronic components onto glass substrates. In order to address the issue, a laser assisted bonding process is proposed to utilize laser energy in the bonding of electronic components onto glass substrates. Since glass has a relatively high transmission rate for laser lights, it allows for a majority of a laser beam to pass therethrough to heat and reflow the solder material between the glass substrate and the electronic components, without too much energy loss. In this way, energy consumption can be reduced compared to the bonding processes for silicon substrates or polymer substrates. Also, since the laser energy can be applied in a shorter period than conventional heating processes, the time needed for the bonding process can be reduced significantly, which also improves efficiency of the bonding process.

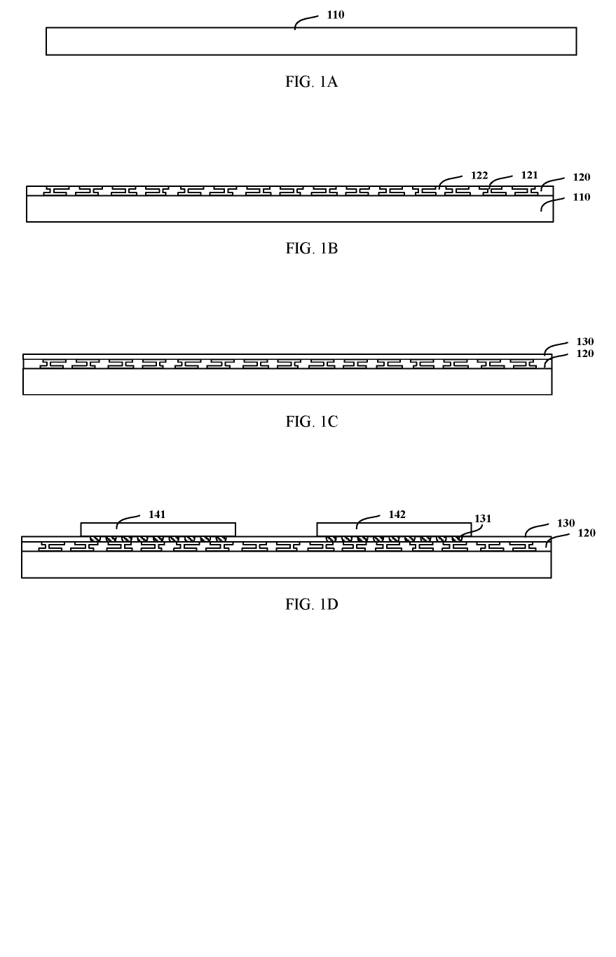

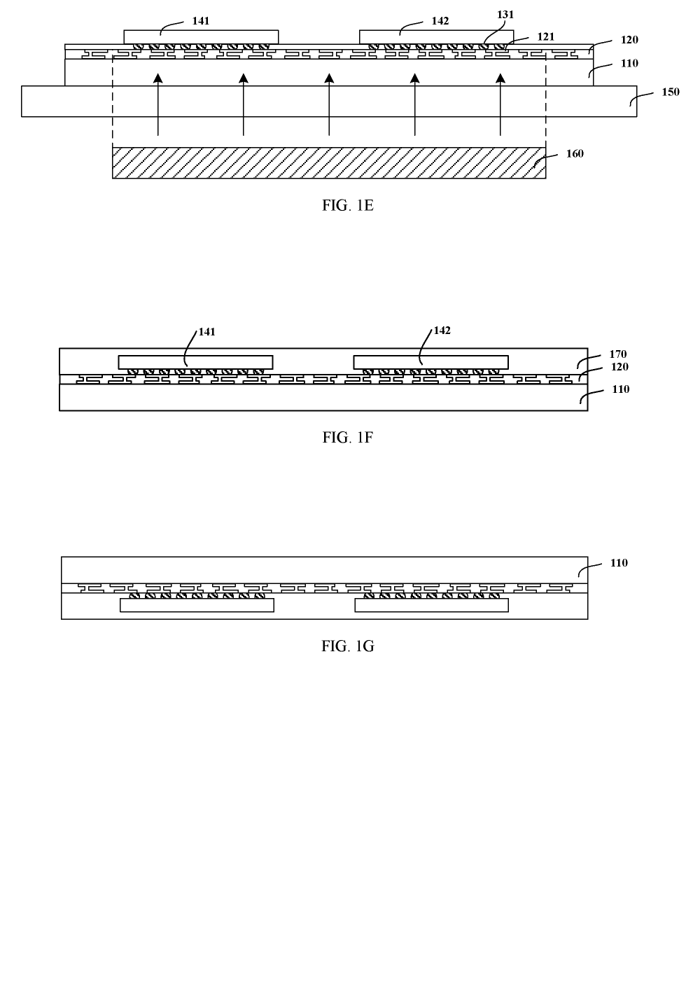

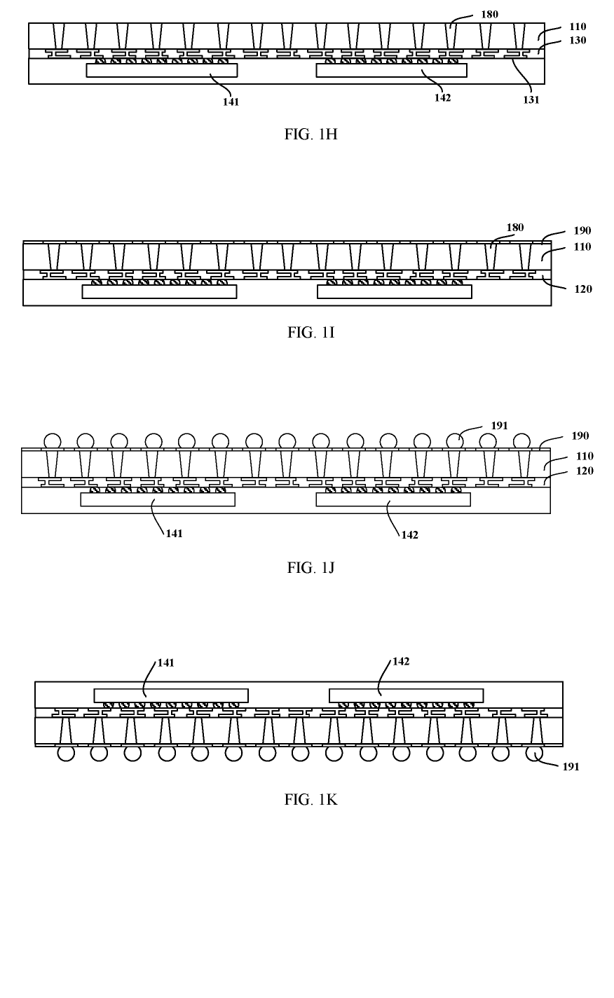

FIGS. 1A to 1K show cross-sectional views illustrating a method for forming an electronic device according to an embodiment of the present application. In the embodiment, a glass substrate is used as a base of the electronic device, and a corresponding bonding method is used in the forming of the electronic device.

Referring to FIG. 1A, a glass substrate 110 is provided. The material of the glass substrate 110 can be changed to allow tailoring of glass properties to specific applications. For example, the glass substrate 110 may include high borosilicate glass or quartz glass. Preferably, the glass substrate 110 may have a transmission rate of more than 80% for light beam with a wavelength between 350 nm to 1100 nm, or preferably between 400 nm to 700 nm. In some embodiments, the glass substrate 110 has a thickness of 300 um to 1500 um. As aforementioned, compared with silicon substrates or polymer substrates which have been widely used in semiconductor packages, glass substrates may offer superior thermal stability, optical transparency, chemical resistance, etc. Utilizing the unique properties of glass substrates can overcome the limitations of silicon wafers, fostering the development of more advanced and reliable semiconductor packages or devices.

Various additional structures will be formed in or on the glass substrate 110 to impart electrical connection capability to the glass substrate 110, as elaborated below. Referring to FIG. 1B, in some embodiments, a top redistribution layer 120 is formed on a top surface of the glass substrate 110. The top redistribution layer 120 can include conductive structures 121 passing through a dielectric layer 122 for providing electrical connection between a top surface and a bottom surface of the top redistribution layer 120. It can be appreciated that the conductive structures 121 may include conductive patterns exposed from both of the top surface and bottom surface of the top redistribution layer 120, such that electronic components or structures at both sides of the top redistribution layer 120 can be electrically coupled with each other when they are connected to the top or bottom conductive patterns. Preferably, the conductive structures 121 have a good thermal conductivity. The top redistribution layer 120 may adopt any material compatible with the glass substrate 110 and fit for a redistribution layer. Preferably, the conductive structures 121 may be made of copper, aluminum, silver or other metal materials or combination thereof. It can be understood that, in some embodiments, the glass substrate 110 may be preformed with the top redistribution layer 120. For example, the top redistribution layer 120 may be consisting of the same material as the glass substrate 110, as a part of the glass substrate 110, especially when the top redistribution layer 120 includes a small number (e.g., one or two) of layers of conductive structures 121.

Referring to FIG. 1C, in some embodiments, a non-conductive layer 130 such as a non-conductive paste (NCP) or a non-conductive film (NCF) layer is formed on the top redistribution layer 120, opposite to the glass substrate 110. The non-conductive layer 130 may include an adhesive material or an adhesive tape, and therefore, may assist further attachment of one or more electronic components onto the top redistribution layer 120. Preferably, the non-conductive layer 130 may be formed by dispensing epoxy resin and any suitable filler, and curing during laser bonding. The solder material distributed in the patterned non-conductive layer 130 can be electrically isolated from each other. For example, the anisotropic NCF or NCP layer may include small-diameter resin pellets, which are Ni/Au-coated, dispersed in an insulative resin including an epoxy resin or a cyanate ester resin as a base. Preferably, the non-conductive layer 130 may have a lower light absorption characteristic and a smaller thermal distortion characteristic than the solder material which is also formed on the top redistribution layer 120. As such, the non-conductive layer 130 may exhibit better stability during a subsequent bonding process which will be elaborated below in more details.

Referring to FIG. 1D, after the non-conductive layer 130 and the solder material 131 is formed, one or more electronic components 141, 142 may be attached on the top redistribution layer 120 through the non-conductive layer 130 and the solder material 131. It can be understood that the electronic components 141 and 142 may be the same as each other, or different from each other. Preferably, a portion or all of the electronic components 141, 142 and any other electronic components mounted on the top redistribution layer 120 may be a semiconductor die or a semiconductor package. It can be understood that the number, size and/or type of the electronic components on the top redistribution layer 120 may vary as desired. The electronic components 141, 142 are connected with the solder material 131, such that they can be electrically coupled to the conductive structures in the top redistribution layer 120. It can be understood that, during attachment, a suitable pressure may be applied such that the one or more electronic components 141, 142 are in contact with a top surface of the top redistribution layer 120 via the solder material 131.

Referring to FIG. 1E, laser assisted bonding may be applied through the glass substrate 110 to bond the electronic components 141, 142 onto the top redistribution layer 120 by heating and reflowing the solder material 131 under the electronic components 141, 142. For example, the glass substrate 110 may be disposed on a transparent carrier 150 such as a quarts platform, and a laser source 160 may be disposed under the transparent carrier 150. A laser beam may be emitted from the laser source 160 towards the top redistribution layer 120 and the solder material 131, through the transparent carrier 150 and the glass substrate 110. Since the transparent carrier 150 and the glass substrate 110 are both transparent to the laser beam emitted from the laser source 160, a large portion of the energy of the laser beam may reach at least the top redistribution layer 120, without significant loss in the transparent carrier 150 and the glass substrate 110.

In particular, as the laser energy can directly and effectively reach the conductive structures 121 of the top redistribution layer 120, most photons (e.g., for the laser beam of a wavelength ranging from 400 to 700 nm) are absorbed by the conductive structures 121 in the top redistribution layer 120. As a result, the absorbed laser energy can be transformed into heat which can be transferred throughout the conductive structures 121 in the top redistribution layer 120, due to a higher thermal conductivity of the conductive structures 121 (e.g., copper) than the dielectric material of the top redistribution layer 120. The conductive structures 121 may further transfer heat to the solder material 131 which is directly connected with the conductive structures 121, to heat and reflow the solder material 131 and bond the electronic components 141, 142 with the top distribution layer 120 together via the solder material 131. It can be appreciated that the temperature of the solder material 131 during the bonding process should generally be higher than a melting temperature of the solder material 131, which can be controlled by the irradiation power and time. In a specific example, a laser source (for example, having a wavelength ranging between 400 nm and 700 nm) is employed, for a duration ranging between 1 second and 5 seconds (for example, 2 seconds, 3 seconds, 4 seconds, etc.). However, the present application is not limited to the above example, and the wavelength of the laser source and the duration of irradiation may vary depending on the intensity of the laser beam, the material and the volume of the solder material 131, etc.

FIG. 4 illustrates a temperature profile of a solder material on a glass substrate during a laser assisted bonding process according to an example of the present application. As shown in FIG. 4, the glass substrate may be preheated to 70 centi-degrees, for example, by a heater, before a laser beam is irradiated to the glass substrate. Then at the beginning of the laser assisted bonding process, the laser source may be turned on to emit the laser beam to the glass substrate. The emission of the laser beam may last for one second, for example. During an earlier stage of the duration of the bonding process, the temperature of the solder material may ramp up from 70 centi-degrees to about 240 centi-degrees in a very short period such as 0.3 second. Subsequently during a later stage of the duration of the bonding process, the temperature of the solder material may be maintained at around 240 to 260 degrees, which is higher than the melting temperature of the solder material such as tin or a tin alloy or mixture. Afterwards, the laser beam may be removed from the glass substrate, which allows the solder material to cool down, for example, to around 70 centi-degrees or even lower. After experiencing the change in temperature shown in FIG. 4, the electronic components can be bonded onto the top redistribution layer of the glass substrate via the solder material as desired.

It can be appreciated that the combination of the glass substrate and the top redistribution layer not only reduces power consumption during the bonding process, but not direct or focus the energy to the region where the solder material is formed. Such mechanism further improves the efficiency of the laser assisted bonding process. In some embodiments, the conductive structures in the top redistribution layer may have different distribution or density based on the location of the solder material. In other words, the top redistribution layer may have denser conductive structures at a region under the solder material (i.e., under the electronic components), than another region which is not under the solder material. In this way, the absorption of the laser energy by the top redistribution layer can be more focused, which facilitates the heating of the solder material. In some alternative embodiments, the laser beam emitted from the laser source may be patterned or shaped, such that it may only be aligned with or scan the portions of the top redistribution layer under the solder material, rather than the entirety of the top redistribution layer.

Compared with conventional methods, applying laser assisted bonding from the back side of the glass substrate allows for relatively direct and efficient laser transmission, and therefore, such bonding method is efficient and fast, and can also reduce energy consumption.

Further, in some embodiments, when the one or more electronic components are bonded in the laser assisted bonding process, the non-conductive layer can also be cured. The cured non-conductive layer may protect the solder material. It can be understood that, such process can be relatively efficient since both the bonding of the electronic components and the curing of the non-conductive layer can be completed at the same time.

After the electronic components are bonded onto the top redistribution layer and thus connected with the glass substrate, various other processes may be performed to form an integrated electronic device. Referring to FIG. 1F, an encapsulant layer 170 is formed on the glass substrate 110 to encapsulate the electronic components 141, 142 and the top redistribution layer 120. In some embodiments, the encapsulant layer 170 can be a polymer composite material, such as epoxy resin, epoxy acrylate, or any suitable polymer with or without filler. The encapsulant layer 170 may be non-conductive, provide structural support, and environmentally protect the electronic devices from external environment and contaminants. The encapsulant layer 170 may be formed with any shape as desired. The encapsulant layer 170 may be formed by depositing an encapsulant or molding compound on the glass substrate 110 using injection molding, compressive molding, transfer molding, liquid encapsulant molding, vacuum lamination, spin coating, or another suitable processes. It can be understood that, for simplicity, the non-conductive layer is not shown in further steps. The non-conductive layer can be similarly encapsulated within the encapsulant layer 170 and not be removed.

Referring to FIGS. 1G and 1H, the glass substrate 110 may be flipped over such that a bottom surface of the glass substrate 110 faces upwards, and then, through vias 180 may be formed in the glass substrate 110. Specifically, the through vias 180 may be formed by first forming through holes by ablation or drilling and then filling in the through holes a conductive material, such that electrical connections can be formed extending through the glass substrate 110. It can be appreciated that the through vias 180 can be electrically coupled to the conductive structures 131 in the top redistribution layer 130 and thus be further coupled to the electronic components 141 and 142. In the embodiment shown in FIG. 1H, each of the through vias 180 may take the form of a cone, which has a diameter that decreases from top to bottom. It can be understood that the through vias 180 may take any form as desired. Since the through vias 180 are formed after the laser assisted bonding process, they may not affect the bonding process, especially not block the transmission of the laser beam.

Referring to FIG. 1I, a bottom redistribution layer 190 is then formed on a bottom surface of the glass substrate 110. The bottom redistribution layer 190 may provide a larger area of electrical connection from the through vias 180 within the glass substrate 110. The configuration of the bottom redistribution layer 190 is similar as that of the top redistribution layer 120. For example, conductive structures may be formed in the bottom redistribution layer 190, which can be connected to the through vias. Similar as the through vias 180, as the bottom redistribution layer 190 is formed after the bonding process, the conductive structures in the bottom redistribution layer 190 may not affect the laser assisted bonding process.

Referring to FIG. 1J, solder bumps 191 may be further mounted onto the bottom redistribution layer 190 for providing electrical connection to external devices. Therefore, in general, the electronic components 141, 142 can be electrically coupled through the top redistribution layer 120, the glass substrate 110 and the bottom redistribution layer 190, to the solder bumps 191.

Referring to FIG. 1K, in some embodiments, during manufacture, the solder bumps 191 may be mounted while the bottom surface of the glass substrate 110 faces upwards and the electronic components 141, 142 face downwards. For further attachment, the general structure may be flipped over, such that the electronic components 141, 142 face upward, and the solder bumps 191 may be attached to other base underneath.

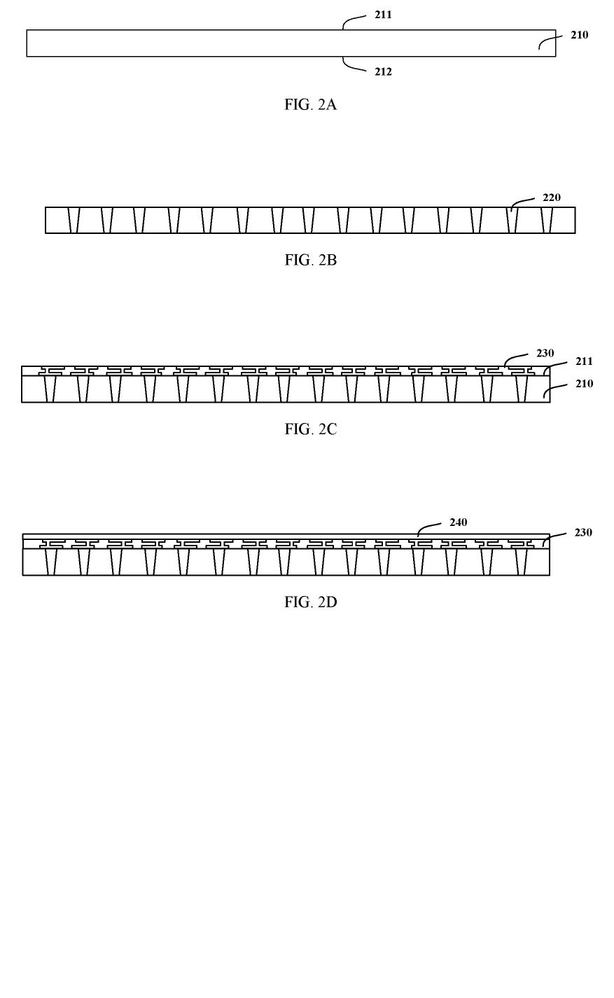

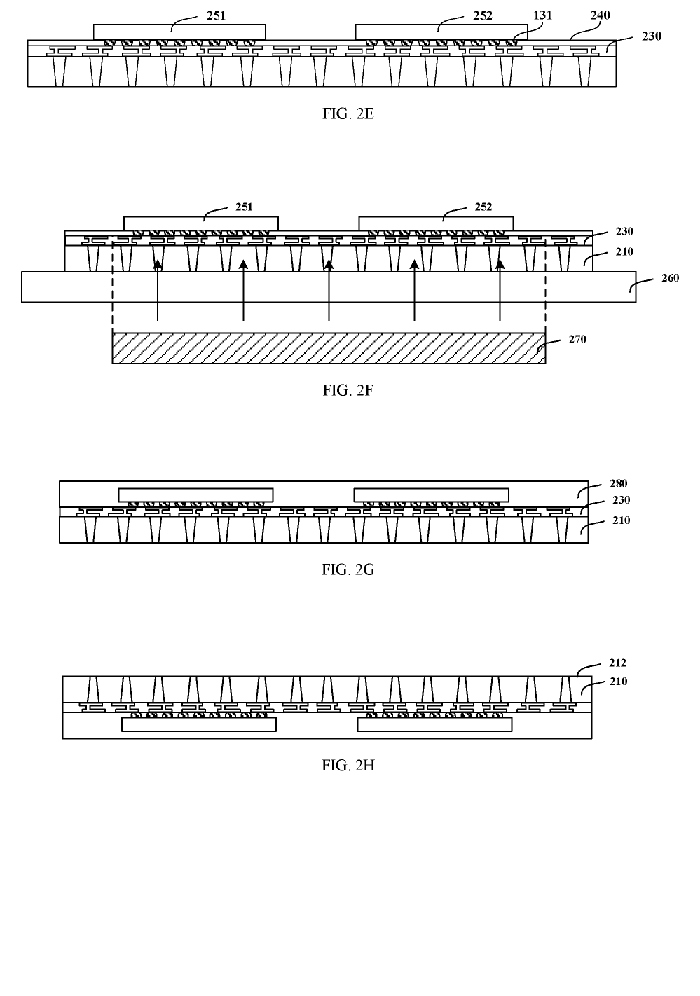

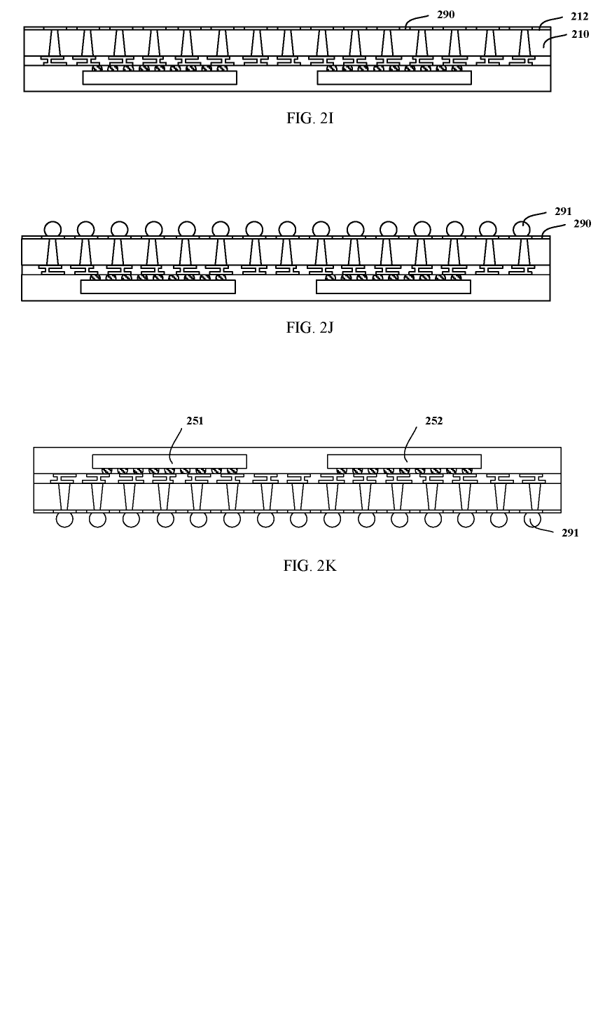

FIGS. 2A to 2K show cross-sectional views illustrating a method for forming an electronic device according to another embodiment of the present application. Different from the embodiment described with reference to FIGS. 1A to 1K, through vias can be formed in a glass substrate before the bonding of electronic components onto the glass substrate.

Referring to FIG. 2A, a glass substrate 210 is provided, which has a top surface 211 and a bottom surface 212. Referring to FIG. 2B, through vias 220 are formed in the glass substrate 210. In some embodiments, the through vias 220 can be formed as a conductive cone with a decreasing diameter from top to bottom.

Referring to FIG. 2C, a top redistribution layer 230 with internal conductive structures is formed on the top surface 211 of the glass substrate 210. Referring to FIG. 2D, a non-conductive layer 240 may be formed on the top redistribution layer 230 for assisting subsequent attachment of electronic components.

Referring to FIG. 2E, one or more electronic components 251, 252 are attached on the top redistribution layer 230. It can be appreciated that a solder material 231 may be formed through the non-conductive layer 240.

Then, referring to FIG. 2F, laser assisted bonding can be applied through the glass substrate 210 to bond the electronic components 251, 252 onto the top redistribution layer 230 via the solder material. Similar as the embodiments mentioned above, in some embodiments, the glass substrate 210 may be disposed on a transparent carrier 260, and a laser source 270 can be disposed under the transparent carrier 260 to emit a laser beam upwards. The laser beam may pass through the transparent carrier 260 and the glass substrate 210 and reach the top redistribution layer 230. In this way, the solder material can be reflowed so as to bond the electronic components 251, 252 onto the top redistribution layer 230.

Referring to FIG. 2G, then, an encapsulant layer 280 may be formed on the glass substrate 210 to encapsulate the electronic components 251, 252 and the top redistribution layer 230. Referring to FIG. 2H, the glass substrate may be then flipped over to expose a bottom surface 212 of the glass substrate 210 for further formation of redistribution layer and attachment of solder bumps.

Referring to FIG. 2I and 2J, a bottom redistribution layer 290 may be formed on the bottom surface 212 of the glass substrate 210, and solder bumps 291 are mounted onto the bottom redistribution layer 290.

Referring to FIG. 2K, the glass substrate may be flipped over again such that the electronic components 251, 252 face upwards and the solder bumps 291 face downwards.

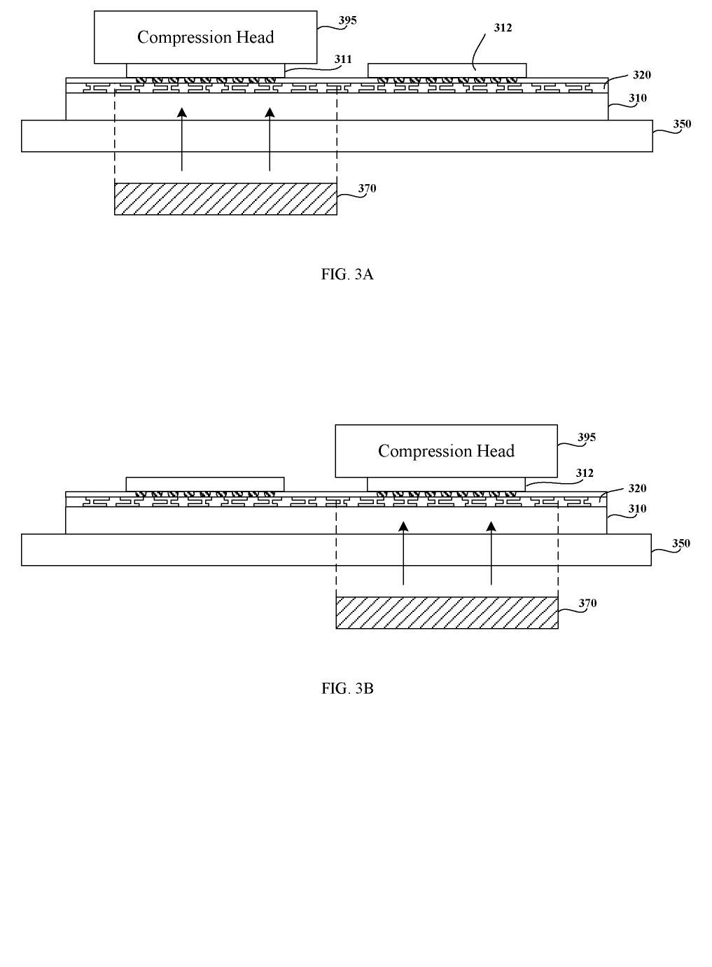

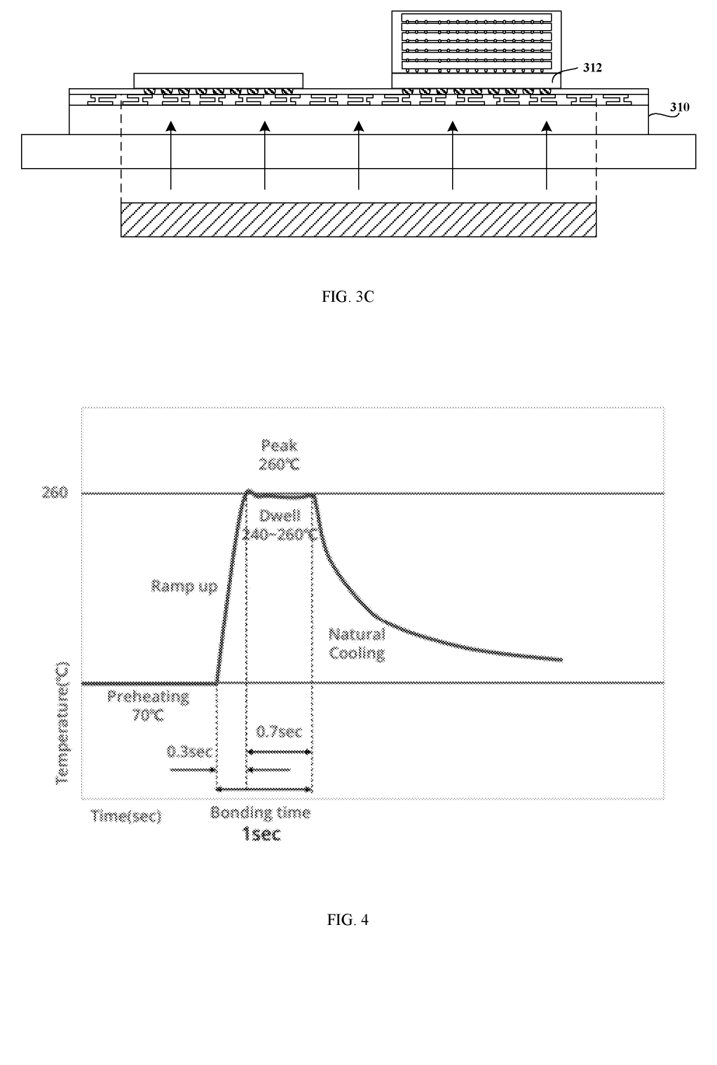

FIGS. 3A to 3C show various alternative ways for applying laser assisted bonding according to some embodiments of the present application.

For example, referring to FIGS. 3A and 3B, in some embodiments, when bonding electronic components 311 and 312 onto a top redistribution layer 320, a bonding process combining thermal compression bonding and laser assisted bonding can be applied to the electronic components 311 and 312 respectively. In particular, when a laser beam is emitted from a laser source towards a solder material between the electronic components 311 and 312 and the top redistribution layer 320 through a transparent carrier 350 and a glass substrate 310, a compression head 395 may apply a compression force at the electronic components 311 and 312 against the top redistribution layer 320. It can be appreciated that the thermal compression bonding by the compression head 395 further improves the bonding between the electronic components 311 and 312 and the top redistribution layer 320.

Referring to FIG. 3C, in some other embodiments, an electronic component 312 or any other electronic component mounted on a glass substrate 310 can be a high bandwidth memory (HBM) chiplet package or other semiconductor packages, rather than a semiconductor die. Although the semiconductor package 312 may not be transparent to a laser beam and thus is not suitable for laser assisted bonding from its top side, the glass substrate 310 which is transparent to a laser beam can allow energy of the laser beam to pass therethrough, similar as those embodiments shown in FIGS. 1A to 1K and 2A to 2K.

The discussion herein included numerous illustrative figures that showed various portions of a method for forming an electronic device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, comprising:
providing a glass substrate, wherein the glass substrate has on its top surface a top redistribution layer;
attaching an electronic component on the top redistribution layer of the glass substrate;
bonding the electronic component onto the top redistribution layer by applying laser assisted bonding through the glass substrate;
forming an encapsulant layer on the glass substrate to encapsulate the electronic component and the top redistribution layer;
forming through vias in the glass substrate;
forming a bottom redistribution layer onto a bottom surface of the glass substrate; and
mounting solder bumps onto the bottom redistribution layer.

2. The method of claim 1, wherein bonding the electronic component onto the top redistribution layer comprises: applying laser assisted bonding through the glass substrate and applying thermal compression to the electronic component.

3. The method of claim 1, wherein the electronic component comprises a semiconductor die or a semiconductor package.

4. The method of claim 1, wherein when the glass substrate has a thickness of 300 um to 1500 um.

5. The method of claim 1, wherein a duration of the laser assisted bonding ranges between 1 second and 5 seconds.

6. The method of claim 1, wherein before attaching an electronic component on the top redistribution layer, the method further comprises: forming a non-conductive layer on the top redistribution layer.

7. A method for forming an electronic device, comprising:
providing a glass substrate, wherein the glass substrate comprises a top surface and a bottom surface;
forming through vias in the glass substrate;
forming a top redistribution layer on the top surface of the glass substrate;
attaching an electronic component on the top redistribution layer;
bonding the electronic component onto the top redistribution layer by applying laser assisted bonding through the glass substrate;
forming an encapsulant layer on the glass substrate to encapsulate the electronic component and the top redistribution layer;
forming a bottom redistribution layer on the bottom surface of the glass substrate; and
mounting solder bumps onto the bottom redistribution layer.

8. The method of claim 7, wherein bonding the electronic component onto the top redistribution layer comprises: applying laser assisted bonding through the glass substrate and applying thermal compression to the electronic component.

9. The method of claim 7, wherein the electronic component comprises a semiconductor die or a semiconductor package.

10. The method of claim 7, wherein the glass substrate has a thickness of 300 um to 1500 um.

11. The method of claim 7, wherein a duration of the laser assisted bonding ranges between 1 second and 5 seconds.

12. The method of claim 7, wherein before attaching an electronic component on the top redistribution layer, the method further comprises: forming a non-conductive layer on the top redistribution layer.
